(19) United States
(12) Patent Application Publication
(10) Pub. No.: US 2016/0211227 A1
(43) Pub. Date: Jul. 21, 2016

(54) Semiconductor Device Including a Protection Structure

(71) Applicant: Infineon Technologies AG, Neubiberg (DE)

(72) Inventors: Eva Wagner, Regensburg (DE); Korbinian Kaspar, Regensburg (DE); Adolf Koller, Regensburg (DE)

(21) Appl. No.: 14/997,946

(22) Filed: Jan. 18, 2016

(30) Foreign Application Priority Data
Jan. 19, 2015 (DE) 102015100671.5

(51) Int. Cl. H01L 23/00; H01L 23/31

(52) U.S. Cl. CPC H01L 23/562; H01L 23/564; H01L 23/3178

(57) ABSTRACT

A device includes a semiconductor chip including a dicing edge. The device further includes an active structure arranged in a semiconductor material of the semiconductor chip, and a protection structure arranged between the dicing edge and the active structure.

### PRIORITY CLAIM

This application claims priority to German Patent Application No. 10 2015 100 671.5 filed on 19 Jan. 2015, the content of said application incorporated herein by reference in its entirety.

### TECHNICAL FIELD

The invention relates to semiconductor devices including a protection structure. In addition, the invention relates to methods for manufacturing such semiconductor devices.

### BACKGROUND

During production and operation of semiconductor devices physical effects such as thermal energy or mechanical force may occur. For example, such effects may result from a dicing process and may have a negative effect on internal structures of a semiconductor wafer to be diced. Semiconductor devices and methods for manufacturing semiconductor devices constantly have to be improved. In particular, it may be desirable to avoid damage of the semiconductor devices and their internal structures.

### SUMMARY

According to an embodiment of a device, the device comprises a semiconductor chip comprising a dicing edge, an active structure arranged in a semiconductor material of the semiconductor chip, and a protection structure arranged between the dicing edge and the active structure.

According to another embodiment of a device, the device comprises a semiconductor chip comprising a dicing edge, an active structure arranged in a semiconductor material of the semiconductor chip, and a trench at least partly arranged in at least one of the semiconductor material, an epitaxial layer of the semiconductor chip, and a buried layer of the semiconductor chip. The trench is arranged between the dicing edge and the active structure, and the trench is filled with an oxide.

According to yet another embodiment of a device, the device comprises a semiconductor chip comprising an active structure and a protection structure at least partly arranged in a semiconductor material of the semiconductor chip and extending along an outline of a frontside of the semiconductor chip. The active structure is enclosed by the protection structure.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of aspects and are incorporated in and constitute a part of this description. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference numerals may designate corresponding similar parts.

FIG. 1 schematically illustrates a cross-sectional side view of a device 100 in accordance with the disclosure.

FIG. 2 schematically illustrates a cross-sectional side view of a further device 200 in accordance with the disclosure.

FIG. 3 schematically illustrates a top view of a further device 300 in accordance with the disclosure.

FIG. 4 schematically illustrates a cross-sectional side view of a further device 400 in accordance with the disclosure.

### DETAILED DESCRIPTION

In the following detailed description, reference is made to the accompanying drawings. The drawings show by way of illustration specific aspects in which the invention may be practiced. In this regard, directional terminology, such as “top”, “bottom”, “front”, “back”, etc., maybe used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present invention. Hence, the following detailed description is not to be taken in a limiting sense, and the concept of the present invention is defined by the appended claims.

As employed in this description, the terms “connected”, “coupled”, “electrically connected” and/or “electrically coupled” are not meant to necessarily mean that elements must be directly connected or coupled together. Intervening elements may be provided between the “connected”, “coupled”, “electrically connected” or “electrically coupled” elements.

Further, the word “over” used with regard to e.g. a material layer formed or located “over” a surface of an object may be used herein to mean that the material layer maybe located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or more additional layers being arranged between the implied surface and the material layer.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures. In addition, the features of the various aspects and examples described herein may be combined with each other, unless specifically noted otherwise.

The devices described herein may include a semiconductor chip. The semiconductor chip may be of arbitrary type and may be manufactured based on arbitrary technologies. For example, the semiconductor chip may include integrated electrical, electro-optical or electro-mechanical circuits, passives, etc. The integrated circuits may be designed as logic integrated circuits, analog integrated circuits, mixed signal integrated circuits, power integrated circuits, memory circuits, integrated passives, micro-electro mechanical systems, etc. The semiconductor chip needs not be manufactured from a specific semiconductor material, for example, Si, SiC, SiGe, GaAs, and, furthermore, may contain inorganic and/or organic materials that are not semiconductors, such as, for example, insulators, plastics, metals, etc. In one example, the semiconductor chip may include an elemental semiconductor material, for example Si, etc. In a further example, the semiconductor chip may include a compound semiconductor material, for example SiC, SiGe, GaAs, etc. The semiconductor chip may be packaged or unpackaged. That is, the semiconductor chip may be at least partly covered by an encapsulation material or not. Semiconductor devices including an encapsulation material may be referred to as semiconductor packages.

The terms “frontside” and “backside” of a semiconductor chip or a semiconductor wafer may be used herein. The term “frontside” may particularly relate to a main face of the semiconductor chip that may include microelectronic components and integrated circuits. Semiconductor chips may be manufactured from semiconductor wafers that may serve as a substrate for microelectronic devices to be built in and over the semiconductor wafer. The integrated circuits may be manufactured by doping, ion implantation, deposition of materials, photolithographic patterning, etc. The manufacturing processes usually may be performed on a specific main surface of the semiconductor wafer which may also be referred to as the “frontside” of the semiconductor wafer. After separating the individual semiconductor chips from the semiconductor wafer, the “frontside” of the semiconductor wafer consequently becomes the “frontside” of the separated semiconductor chips. Contrarily, the term “backside” of a semiconductor chip may refer to a main surface of the semiconductor chip that may be arranged opposite to the frontside of the semiconductor chip. The backside of the semiconductor chip may be free of electronic components, i.e. it may consist of the semiconductor material.

The semiconductor chip may include an active area that may particularly be arranged at (or under) the frontside of the semiconductor chip. The active area may be defined as a physical part of the semiconductor chip containing microelectronic structures or semiconductor structures. The active area may include active structures arranged in the semiconductor material of the semiconductor chip. In general, an active structure may include at least one of a doped region, an electrical component, an integrated circuit, etc. In particular, an active structure may include at least one of a diode, a transistor, a fuse, a transistor, a resistor, a capacitor, etc.

A dicing process may be used for manufacturing the devices described herein. The dicing process may particularly be used to divide or separate a semiconductor wafer into individual multiple semiconductor chips. A laser beam (or laser radiation) maybe used during the dicing process. In one example, a laser stealth dicing technique may be applied. In a further example, a laser ablation (or laser cutting or laser dicing) technique may be applied.

In laser stealth dicing technology, a laser beam of a wavelength capable of transmitting through the semiconductor wafer may be focused onto a point inside the semiconductor wafer. Here, a wavelength of the laser may be chosen depending on the material of the semiconductor wafer. That is, a first wavelength which is suitable for processing a first semiconductor material may differ from a second wavelength which is suitable for processing a different second semiconductor material. For example, suitable wavelengths for processing Si, SiC, GaN may differ from each other. Exemplary suitable wavelengths for processing a wafer made of silicon may have values of about 1064 nanometers or about 1342 nanometers. Due to a non-linear absorption effect, only localized points inside the semiconductor wafer may be selectively laser-machined, whereby damaging the frontside and backside of the semiconductor wafer may be avoided. The semiconductor wafer may be diced by moving the relative positions of the laser beam and the semiconductor wafer in order to scan the semiconductor wafer according to the desired dicing pattern.

In laser ablation technology, material maybe removed from the semiconductor wafer surface by irradiating the surface with a laser beam at a wavelength that may cause the semiconductor chips wafer material to absorb it. Here, surface layers of the semiconductor wafer may be melted and/or vaporized. The depth over which the laser energy is absorbed, and thus the amount of material removed by applied a laser pulses, may depend on at least one of the laser wavelength, the pulse length, optical properties of the material to be cut, etc. The total mass ablated from the target per laser pulse may be referred to as ablation rate.

The semiconductor wafer may be diced by applying the semiconductor wafer on a tape, in particular a dicing tape, apply the dicing pattern, in particular a rectangular pattern, to the semiconductor wafer, e.g. according to one or more of the above mentioned techniques, and pull the tape e.g. along four orthogonal directions in the plane of the tape. By pulling the tape, the semiconductor wafer may be divided into a plurality of semiconductor chips (or dies). The side surfaces of the separated semiconductor chip extending from the backsides of the semiconductor chips to the frontsides of the semiconductor chips may be referred to as dicing edges.

The devices described herein may include an epitaxial layer that may be arranged in the semiconductor chip. Epitaxy may refer to a deposition of a crystalline overlayer on a crystalline substrate, for example a semiconductor material of a semiconductor chip or a semiconductor wafer. A purpose of epitaxy may be to grow a silicon layer of uniform thickness and accurately controlled electrical properties such that a suitable substrate for subsequent device processing may be provided. The epitaxial layer may be regarded as a part of the semiconductor material of the semiconductor chip or not.

The devices described herein may include a buried layer that may be arranged in the semiconductor chip. The buried layer may be an electrically conductive layer that may be arranged over the semiconductor material of the semiconductor chip or a semiconductor wafer. The buried layer may be diffused prior to introducing an epitaxial layer. For example, a buried layer may be used to increase a conductivity of a bipolar junction transistor or similar components. The buried layer may be regarded as a part of the semiconductor material of the semiconductor chip or not.

The devices described herein may include a seal ring that may be arranged in the semiconductor chip. The seal ring may be configured to reduce or avoid an intrusion of cracks into an inner circuitry of the semiconductor chip. In addition, the seal ring may be configured to prevent moisture penetration or chemical damage of the inner circuitry. In one example, the seal ring may include layers of dielectric and metal patterns. In particular, the seal ring may consist of multiple stacked metal layers that may be connected by metal plugs. A dielectric material, such as e.g. an oxide, may be arranged between the metal layers and metal plugs.

The devices described herein may include a crack stop layer that may be arranged in the semiconductor chip. Cracks may occur at the semiconductor chip edges or corners and may propagate towards a center of the semiconductor chip. In this regard, the crack stop layer may be configured to reduce such crack propagation from the semiconductor chip edges or corners to the center of the chip. For example, the crack stop layer be structured and designed similar to a seal ring as described above.

The devices described herein may include a protection structure that may be arranged in the semiconductor chip. The protection structure may be configured to protect inner structures of the semiconductor chip during a fabrication and/or operation of the device including the semiconductor chip. In particular, the protection structure may be configured to protect an active structure of the semiconductor chip by absorbing at least one of thermal energy and mechanical force. For example, electromagnetic radiation may scatter into active regions of the semiconductor chip during a dicing process, for example during a stealth dicing process or a laser dicing process. Here, the protection structure maybe configured to absorb the scattered radiation and/or thermal energy resulting thereof. Furthermore, the protection structure maybe configured to absorb a mechanical force that may result from crack propagating towards the active structure.

The protection structure may correspond to or may include a trench filled with a protection material. For example, the filled trench may be at least partly arranged in a semiconductor material of the semiconductor chip. In addition, the filled trench may at least partly be arranged in one or more additional layers, for example in at least one of an epitaxial layer and a buried layer. The trench may e.g. be manufactured based on trench techniques (or trench technologies), in particular deep trench techniques. In this connection, producing the trench may include an etching act, in particular deep reactive ion etching, a Bosch process, etc.

The trench may be filled with any kind of material suitable to absorb thermal energy and/or mechanical force as mentioned above. In particular, the trench may be at least partly filled with an oxide material. In one example, the trench may be filled with only one type of oxide. In a further example, the trench may include various regions or layers of different oxides. For example, a side wall of the trench may be covered with a first oxide while a remaining part of the trench may be filled with a second oxide that may differ from the first oxide. Compared to the second oxide, the first oxide may be faster growing.

The protection structure may particularly be arranged between a dicing edge of the semiconductor chip and an active structure of the semiconductor chip. In this regard, the protection structure may be spatially separated and structurally distinguishable from the active structure of the semiconductor chip. Similarly, the protection layer may be spaced apart or arranged distant from the dicing edge of the semiconductor chip. That is, the protection structure may be completely arranged inside the semiconductor chip and may thus not form a peripheral part of the semiconductor chip.

The protection structure may be spaced apart a distance from the dicing edge of the semiconductor chip, wherein a minimum value of the distance may lie in a range from about 3 micrometer to about 7 micrometer. In particular, the protection structure may be spaced apart at least about 5 micrometer from the dicing edge. Further, the protection structure may be spaced apart a distance from a frontside (or front surface) of the semiconductor chip, wherein a value of the distance may lie in a range from about zero micrometer to about 25 micrometer. Here, the distance may particularly depend on the specific type of semiconductor chip that is to be manufactured. A minimum value of the distance may correspond to a distance between the frontside of the semiconductor chip and the frontside of the semiconductor material in the semiconductor chip such that the protection structure may be completely embedded in the semiconductor material.

The protection structure may particularly extend in a direction parallel to a dicing edge of the semiconductor chip. A spatial dimension of the protection structure may depend on the technique chosen for manufacturing the protection structure. For example, when forming a protection structure by filling a trench with an oxide material as described herein, it may be technically possible to fill the trench with the oxide material to a certain depth of the trench but not beyond. That is, a maximum dimension of the protection structure in a direction parallel to the dicing edge may be limited by the technique that is chosen for producing the protection structure. In general, it may be desirable to maximize a dimension of the protection structure in a direction parallel to the dicing edge if technically possible. In a non-limiting example, a dimension of the protection structure may be at least about 1 micrometer, more particular at least about 2 micrometer, in a direction parallel to a frontside of the semiconductor chip. In addition, a dimension of the protection structure may be at least about 5 micrometer, more particular at least about 10 micrometer, more particular at least about 15 micrometer, and even more particular at least about 20 micrometer, in a direction parallel to a dicing edge of the semiconductor chip.

The protection structure may not be limited to be exclusively arranged at one single dicing edge of the semiconductor chip. Instead, the protection structure may be arranged at an arbitrary number of dicing edges of the semiconductor chip depending on the specific arrangement of the active structures that are to be protected by the protection structure. In particular, the protection structure may extend along an outline of a frontside of the semiconductor chip such that the active structures of the semiconductor chip may be enclosed by the protection structure. In one example, the protection structure may completely enclose the active structures when viewed in a direction perpendicular to the frontside of the semiconductor chip.

For the case of the semiconductor chip including a seal ring and/or a crack stop layer, the protection structure may be arranged under the seal ring and/or the crack stop layer. In this regard, the protection structure may be spatially separated and structurally distinguishable from the seal ring and/or the crack stop layer. For example, while the protection structure may be arranged in at least one of a semiconductor material, an epitaxial layer and a buried layer, the seal ring and/or the crack stop layer may be arranged over these material regions. Furthermore, the protection structure may be manufactured from an oxide while the seal ring and/or the crack stop layer may at least partly include one or more metal structures.

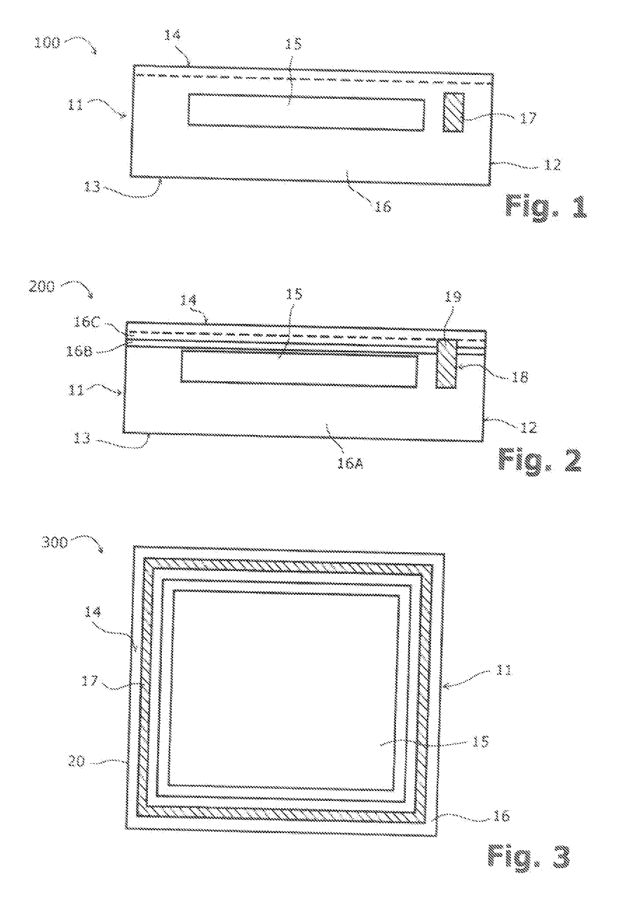

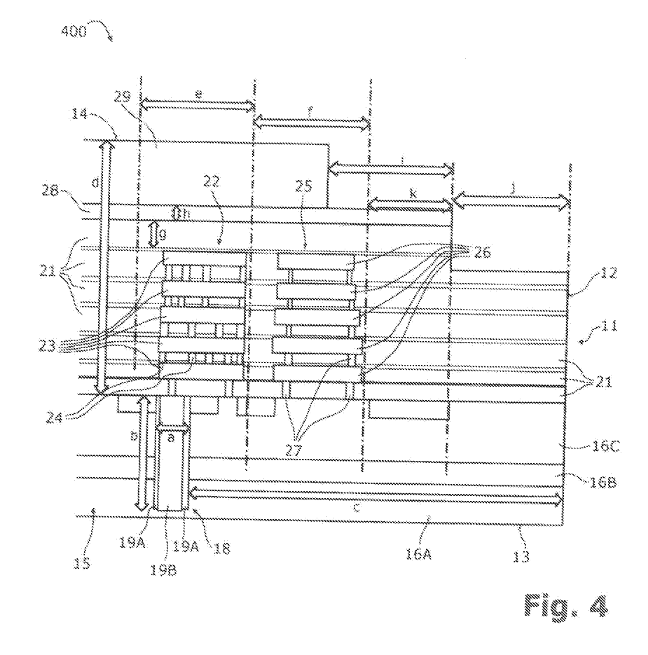

FIGS. 1 to 3 schematically illustrate devices 100 to 300 as basic concepts of the present invention. Hence, the devices 100 to 300 are shown in a general manner and may include further components that are not illustrated for the sake of simplicity. A more detailed device 400 similar to the devices 100 to 300 is described in connection with FIG. 4. Each of the devices 100 to 300 shown in FIGS. 1 to 3 may additionally include one or more of the components described in connection with FIG. 4.

FIG. 1 schematically illustrates a cross-sectional side view of a device 100 in accordance with the disclosure. The device 100 includes a semiconductor chip 11 having a dicing edge 12. The dicing edge 12 may correspond to a side surface of the semiconductor chip 11 that may extend from a backside 13 of the semiconductor chip 11 to a frontside 14 of the semiconductor chip 11. The device 100 further includes an active structure 15 that may particularly be arranged at or under the frontside 14 of the semiconductor chip 11. The active structure 15 is arranged in a semiconductor material 16 of the semiconductor chip 11. In the example of FIG. 1, a dashed line is included to indicate a qualitative boundary between the semiconductor material 16 and further material regions of the semiconductor chip 11 that may be arranged between the frontside 14 and the semiconductor material 16. For example, a passivation layer may be arranged over the semiconductor material 16. In this connection, a more detailed exemplary structure of a semiconductor chip is described in connection with FIG. 4. The device 100 further includes a protection structure 17 arranged between the dicing edge 12 and the active structure 15. In particular, the protection structure 17 may be arranged between the dicing edge 12 and the active structure 15 when viewed in a direction substantially perpendicular to the dicing edge 12. The protection structure 17 may particularly be configured to protect the active structure 15 from damage that may result from physical effects, such as e.g. thermal energy, mechanical force, etc. that may occur during a production and operation of the device 100.

FIG. 2 schematically illustrates a cross-sectional side view of a further device 200 in accordance with the disclosure. The device 200 includes a semiconductor chip 11 having a dicing edge 12. The device 200 further includes an active structure 15 arranged in a semiconductor material 16A of the semiconductor chip 11. The device 200 may include further optional layers that may be arranged over the semiconductor material 16A, for example one or both of a buried layer 16B and an epitaxial layer 16C. The buried layer 16B and/or the epitaxial layer 16C may be regarded as a part of semiconductor material 16A of the semiconductor chip 11 or not. The device 200 further includes a trench 18 at least partly arranged in at least one of the semiconductor material 16A, the buried layer 16B and the epitaxial layer 16C. The trench 18 is arranged between the dicing edge 12 and the active structure 15 and filled with an oxide 19. The filled trench 18 of the device 200 may serve a similar purpose as the protection structure 17 of the device 100.

FIG. 3 schematically illustrates a top view of a further device 300 in accordance with the disclosure. For example, the device 300 may be similar to one or both of the devices 100 and 200 when viewed from their frontsides (or topsides). The device 300 includes a semiconductor chip 11 having an active structure 15. The active structure 15 may particularly be arranged at or under a frontside 14 of the semiconductor chip 11. That is, the active structure 15 may not necessarily be visible or exposed from an outside of the semiconductor chip 11. The device 300 further includes a protection structure 17 at least partly arranged in a semiconductor material 16 of the semiconductor chip 11. The protection structure 17 extends along an outline 20 of the frontside 14 of the semiconductor chip 11. In the example of FIG. 3, the protection structure 17 is indicated to extend along the outline 20 of the semiconductor chip 11. In this regard, it is to be noted that the protection structure 17 may not be visible or exposed from an outside of the semiconductor chip 11. Instead, the protection structure 17 may particularly be arranged inside the semiconductor chip 11 and thus spaced apart from the surface of the frontside 14 of the semiconductor chip 11. The protection structure 17 is arranged such that the active structure 15 is enclosed by the protection structure 17.

FIG. 4 schematically illustrates a cross-sectional side view of a further device 400 in accordance with the disclosure. The device 400 maybe seen as a more detailed version of the devices 100 to 300 of FIGS. 1 to 3. Comments made in connection with the example of FIG. 4 may thus also hold true for the examples of FIGS. 1 to 3.

The device 400 may include a semiconductor chip 11 having a backside 13, a frontside 14 and a side surface 12 extending from the backside 13 to the frontside 14. The side surface 12 may particularly correspond to a dicing edge of the semiconductor chip 11. The dicing edge 12 may result from a dicing process that may have been used for separating the semiconductor chip 11 from a semiconductor wafer. For example, the dicing edge 12 may result from at least one of a stealth dicing process, a laser dicing process, and a laser ablation process. In the example of FIG. 4, a side surface (or dicing edge) of the semiconductor chip 11 opposite to the dicing edge 12 is not explicitly shown for illustrative purposes.

The semiconductor chip 11 may include an arbitrary semiconductor material 16A, for example an elemental semiconductor material, such as e.g. silicon, or a compound semiconductor material, such as e.g. GaAs. A (highly-doped) buried layer 16B maybe arranged over the semiconductor material 16A. The buried layer 16B may be regarded as a part of the semiconductor material 16A or not. In addition, an epitaxial layer 16C may be arranged over the semiconductor material 16A and the buried layer 16B (if present). The epitaxial layer 16C maybe regarded as a part of the semiconductor material 16A or not.

The semiconductor chip 11 may include a protection structure 18 that may be arranged at least partly in at least one of the semiconductor material 16A, the buried layer 16B and the epitaxial layer 16C. In the example of FIG. 4, the protection structure 18 may entirely extend through the buried layer 16B and the epitaxial layer 16C. In addition, the protection structure 18 may extend at least partly into the semiconductor material 16A, but may not fully reach the backside 13 of the semiconductor chip 11.

In general, the protection structure 18 maybe of arbitrary shape and dimension. In particular, the protection structure 18 may have a form that may result from applying a deep trench technique for manufacturing the protection structure 18. A dimension “a” of the protection structure 18 may be at least about 1 micrometer, more particular at least about 2 micrometer, in a direction parallel to the frontside 14 of the semiconductor chip 11. A further dimension “b” of the protection structure 18 may be at least about 5 micrometer, more particular at least about 10 micrometer, more particular at least about 15 micrometer, and even more particular at least about 20 micrometer, in a direction parallel to the dicing edge 12 of the semiconductor chip 11.

The protection structure 18 may be spaced apart a distance “c” from the dicing edge 12, wherein a minimum value of the distance “c” may lie in a range from about 3 micrometer to about 7 micrometer. In one specific example, the distance “c” may have a value of at least about 5 micrometer. In addition, the protection structure 18 may be spaced apart a distance “d” from the frontside 14 of the semiconductor chip 11, wherein a value of the distance “d” may lie in a range from about zero micrometer to about 25 micrometer. In one non-limiting example, the distance “d” may have a value of at least about 15 micrometer.

In the example of FIG. 4, the protection structure 18 may correspond to a trench that may have been manufactured after the buried layer 16B and the epitaxial layer 16C may have been deposited and before further components may be manufactured over the epitaxial layer 16C. For example, the protection structure 18 may be manufactured based on a deep trench technique that may also be used for producing other structures of the semiconductor chip 11, for example electrical components or integrated circuits of the active region 15. In this regard, it may thus be possible to manufacture the protection structure 18 and these other structures simultaneously. Hence, no additional technique may be required for manufacturing the protection structure 18, because the required manufacturing steps may be performed anyway for producing the other structures.

First, an empty trench 18 maybe formed. Then, the obtained cavity may be filled with a material suitable for absorbing thermal energy and/or mechanical force. For example, the cavity may be filled with one or more oxides. In the example of FIG. 4, the side walls of the trench 18 may be filled with a first oxide 19A that may particularly correspond to a fast growing oxide. In addition, at least a part of the remaining cavity may be filled with a second oxide 19B that may differ from the first oxide 19A. In the illustrated example, the remaining part of the cavity may be completely filled up with the second oxide 19B such that the upper surface of the protection structure 18 may be substantially flush with the upper surface of the epitaxial layer 16C. The bottom of the trench 18 maybe covered with the first oxide 19A, the second oxide 19B, or both.

The device 400 may include one or more active structures 15 that may be arranged in the semiconductor material 16A. The active structures 15 may also extend into further regions of the semiconductor chip 11, for example into the buried layer 16B. The active structures 15 may include at least one of a doped region, an electrical component, and an integrated circuit. In the example of FIG. 4, the active structures 15 are shown to be arranged close to the backside 13 of the semiconductor chip 11 for illustrative purposes. However, it is to be noted that the active structures 15 may particularly be manufactured at (or close to) the frontside 14 of the semiconductor chip 11. That is, when regarding the actual quantitative dimensions of the semiconductor chip 11, the active structures 15 may actually be arranged closer to the frontside 14 of the semiconductor chip 11 than to the backside 13 of the semiconductor chip 11. As can be seen from the example of FIG. 4, the protection structure 18 may particularly be arranged between the dicing edge 12 and the active structures 15. Due to the chosen arrangement of the protection structure 18, the active structures 15 maybe protected by the protection structure 18 from negative physical effects, for example thermal energy and/or mechanical force.

The device 400 may further include one or more oxide layers 21 that may be arranged over the epitaxial layer 16C. A seal ring 22 may be arranged in the oxide layers 21. The seal ring 22 may include multiple metal layers (or metal patterns) 23 that may be substantially arranged in parallel to each other. The metal layers 23 may be connected by metal plugs (or metal vias) 24. The metal components 23, 24 of the seal ring 22 may be embedded in the material of the oxide layers 21 such that the oxide maybe arranged between the metal plugs 24 and possible gaps of the metal layers 23. For example, the seal ring 22 may extend along an outline of the frontside 14 of the semiconductor chip 11 (see FIG. 3). A dimension “e” of the seal ring 22 in a direction parallel to the frontside 14 of the semiconductor chip 11 may lie in a range from about 8 micrometer to about 10 micrometer. In one specific example, the dimension “e” of the seal ring 22 may have a value of about 9 micrometer.

A crack stop layer 25 may be arranged in the oxide layers 21. The crack stop layer 25 may be structured similar to the seal ring 22. That is, the crack stop layer 25 may include multiple metal layers (or metal patterns) 26 that may be connected by metal plugs (or metal vias) 27. The metal components 26, 27 of the crack stop layer 25 may be embedded in the material of the oxide layers 21. Similar to the seal ring 22, the crack stop layer 25 may extend along an outline of the frontside 14 of the semiconductor chip 11. A dimension “f” of the metal components 26, 27 of the crack stop layer 25 may lie in a range from about 3 micrometer to about 5 micrometer. In one specific example, the dimension “f” may have a value of about 4 micrometer. The crack stop layer 25 may also be defined to include an additional region of oxide material (see oxide region of dimension “k”) adjacent to the metal components 26, 27. The dimension “k” of the additional oxide region may lie in a range from about 3 micrometer to about 5 micrometer. In one specific example, the dimension “k” may have a value of about 4 micrometer. Hence, a total width of the crack stop layer 25 may correspond to a sum of the dimensions “f” and “k” and may thus lie in a range from about 6 micrometer to about 10 micrometer. In one specific example, the total dimension may have a value of about 9 micrometer.

The device 400 may include a further layer 28 that may be arranged over the oxide layers 21. The layer 28 may e.g. serve as a first protection (or passivation) layer 28. In one example, the first protection layer 28 may be manufactured from a nitride material. A distance “g” from an upper surface of the seal ring 22 to a lower surface of the first protection layer 28 may lie in a range from about 900 nanometer to about 1100 nanometer. In one specific example, the value of the distance “g” may be about 1000 nanometer. The first protection layer 28 may have a thickness “h” that may lie in a range from about 350 nanometer to about 500 nanometer. In one specific example, the thickness “h” may have a value of about 420 nanometer.

The device 400 may include a further layer 29 that may be arranged over the first protection layer 28. The layer 29 may e.g. serve as a second protection (or passivation) layer 29. In one example, the second protection layer 29 may be manufactured from an imide material and may particularly form a peripheral region of the semiconductor chip 11.

In the example of FIG. 4, the frontside 14 of the semiconductor chip 11 may include a part of the upper surface of the first protection layer 28, a part of the upper surface of the second protection layer 29 and a part of the upper surface of the oxide layers 21. The shape (or kerf) of the frontside 14 may particularly depend on the dicing technique that may have been used for separating the semiconductor chip 11 from a semiconductor wafer. In the example of FIG. 4, the shape of the frontside 14 is illustrated to have the form of multiple steps. However, further possible shapes of the frontside 14 may be possible and differ from FIG. 4. For example, the steps in FIG. 4 may be replaced by the form of a continuous ramp without any steps.

A distance “i” from a side surface of the first step (see left part of FIG. 4) to a side surface of the adjoining second step (see middle part of FIG. 4) may lie in a range from about 5 micrometer to about 7 micrometer. In one specific example, the distance “i” may have a value of about 6 micrometer. A distance “j” from a side surface of the second step (see middle part of FIG. 4) to the dicing edge 12 of the semiconductor chip 11 may lie in a range from about 14 micrometer to about 18 micrometer. In one specific example, the distance “j” may have a value of about 16 micrometer.

It is noted that the components and their relative spatial arrangement as illustrated in FIG. 4 is exemplary and in no way limiting. The basic concepts of the present invention may be still fulfilled even when the spatial arrangement of one or more of the illustrated components maybe changed. For example, the protection structure 18 may be arranged under the seal ring 22 as shown in FIG. 4. However, in further examples, the protection structure 18 may also be shifted in a lateral direction parallel to the frontside 14 of the semiconductor chip 11. In general, the protection structure 18 may be laterally shifted anywhere between the active structures 15 and the dicing edge 12, thereby protecting the active structures 15 from possible physical effects such as e.g. thermal energy or mechanical force. In one example, the protection structure 18 may be arranged under the crack stop layer 25. In a further example, the protection structure 18 may be arranged somewhere under the oxide region of dimension “k”. In yet a further example, the protection structure 18 may be arranged somewhere under the oxide region of width “j”.

While a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the term “exemplary” is merely meant as an example, rather than the best or optimal. It is also to be appreciated that features and/or elements depicted herein are illustrated with particular dimensions relative to each other for purposes of simplicity and ease of understanding, and that actual dimensions may differ from that illustrated herein.

Although specific aspects have been illustrated and described herein, it will be appreciated by those of ordinary skill in the art that a variety of alternate and/or equivalent implementations maybe substituted for the specific aspects shown and described without departing from the concept of the invention. This application is intended to cover any adaptations or variations of the specific aspects discussed herein. Therefore, it is intended that this invention be limited only by the claims and the equivalents thereof.

What it claimed is:

1. A device, comprising:
a semiconductor chip comprising a dicing edge;
an active structure arranged in a semiconductor material of the semiconductor chip; and
a protection structure arranged between the dicing edge and the active structure.

2. The device of claim 1, wherein the protection structure is arranged in a trench, wherein the trench is at least partly arranged in at least one of the semiconductor material, an epitaxial layer of the semiconductor chip, and a buried layer of the semiconductor chip.

3. The device of claim 1, wherein the protection structure comprises an oxide.

4. The device of claim 1, wherein the protection structure extends along an outline of a frontside of the semiconductor chip, and wherein the active structure is enclosed by the protection structure.

5. The device of claim 1, wherein the protection structure extends in parallel to the dicing edge.

6. The device of claim 1, further comprising a seal ring and/or a crack stop layer, wherein the protection structure is arranged under the seal ring and/or the crack stop layer.

7. The device of claim 1, wherein the protection structure is spaced apart at least 3 micrometer from the dicing edge.

8. The device of claim 1, wherein the protection structure is spaced apart a distance from a front side of the semiconductor chip, wherein a value of the distance lies in a range from zero micrometer to 25 micrometer.

9. The device of claim 1, wherein a dimension of the protection structure is at least 1 micrometer in a direction parallel to a frontside of the semiconductor chip and at least 5 micrometer in a direction parallel to the dicing edge.

10. The device of claim 1, wherein the protection structure is arranged in a trench manufactured by a deep trench technique.

11. The device of claim 1, wherein the protection structure comprises a trench filled with an oxide, and wherein side walls of the trench are covered by a further oxide different from the oxide filling the trench.

12. The device of claim 1, wherein the protection structure is configured to protect the active structure by absorbing at least one of a thermal energy and a mechanical force.

13. The device of claim 1, wherein the protection structure is spaced apart from the active structure.

14. The device of claim 1, wherein the active structure comprises at least one of a doped region, an electrical component, and an integrated circuit.

15. The device of claim 1, wherein the dicing edge results from at least one of a stealth dicing process, a laser dicing process, and a laser ablation process.

16. A device, comprising:
a semiconductor chip comprising a dicing edge;
an active structure arranged in a semiconductor material of the semiconductor chip; and
a trench at least partly arranged in at least one of the semiconductor material, an epitaxial layer of the semiconductor chip, and a buried layer of the semiconductor chip,
wherein the trench is arranged between the dicing edge and the active structure,
wherein the trench is filled with an oxide.

17. The device of claim 16, wherein the trench extends along an outline of a frontside of the semiconductor chip, and wherein the active structure is enclosed by the trench.

18. The device of claim 16, wherein the trench is spaced at least 5 micrometer apart from the dicing edge and at least 15 micrometer apart from a frontside of the semiconductor chip.

19. A device, comprising:
a semiconductor chip comprising an active structure; and
a protection structure at least partly arranged in a semiconductor material of the semiconductor chip and extending along an outline of a frontside of the semiconductor chip,
wherein the active structure is enclosed by the protection structure.

20. The device of claim 19, wherein the protection structure comprises an oxide filled trench arranged in the semiconductor material.
